(19) United States
(12) Patent Application Publication
(10) Pub. No.: US 2021/0384374 A1
(43) Pub. Date: Dec. 9, 2021

(54) SEMICONDUCTOR LIGHT EMITTING DEVICE AND METHOD FOR MANUFACTURING THE SAME

(71) Applicant: Research & Business Foundation Sungkyunkwan University, Suwon-si (KR)

(72) Inventors: Geun Young YEOM, Seoul (KR); Dong Woo KIM, Seoul (KR); Youn Joon SUNG, Yongin-si (KR); Doo San KIM, Suwon-si (KR); Ju Eun KIM, Suwon-si (KR); You Jung GILL, Seoul (KR); Yun Jong JANG, Seoul (KR); Ye Eun KIM, Yongin-si (KR)

(73) Assignee: Research & Business Foundation Sungkyunkwan University, Suwon-si (KR)

(21) Appl. No.: 17/339,036

(22) Filed: Jun. 4, 2021

(30) Foreign Application Priority Data
Jun. 5, 2020 (KR) 10-2020-0068317

(51) Int. Cl. H01L 33/00; H01L 33/24

(52) U.S. Cl. CPC H01L 33/0075; H01L 33/24; H01L 33/0041

(57) ABSTRACT

Disclosed is a method for manufacturing a semiconductor light emitting device. The method includes a first step of forming a semiconductor structure in which a first conductive-type semiconductor layer, an active layer, and a second conductive-type semiconductor layer are sequentially stacked; and a second step of forming a mesa structure by removing a portion of each of the second conductive-type semiconductor layer and the active layer, wherein the second step includes: forming a mesa structure by etching a portion of each of the second conductive-type semiconductor layer and the active layer using a plasma etching process; and performing an atomic layer etching process on a surface of the mesa structure formed by the plasma etching process.

### CROSS-REFERENCE TO RELATED APPLICATION

This application claims a benefit under 35 U.S.C. § 119(a) of Korean Patent Application No. 10-2020-0068317 filed on Jun. 5, 2020, on the Korean Intellectual Property Office, the entirety of disclosure of which is incorporated herein by reference for all purposes.

### BACKGROUND

### Field

The present disclosure relates to a semiconductor light emitting device and a method for manufacturing the same. More particularly, the present disclosure relates to a semiconductor light emitting device and a method for manufacturing the same, which may remove or minimize leakage current due to surface etching damage occurring during an etching process by using an atomic layer etching process, such that the semiconductor light emitting device having more excellent voltage characteristics is obtained.

### Description of Related Art

In general, a process for specifically forming a semiconductor pattern, that is, a mesa structure may include dry etching, in particular, dry etching using plasma. This dry etching may not generate undercuts, due to anisotropic characteristics thereof and may be suitable for microprocesses such as semiconductor manufacturing process. Specifically, a typical example of the plasma dry etching may include an etching scheme using induced coupled plasma (ICP) in which high density plasma is generated by using a magnetic field to generate an induced electric field.

However, the ICP etching scheme which is currently commonly used causes surface etching damage to an etching target site due to energy contained in the plasma ions itself and low etching selectivity, so that the damaged site acts as a path for the current flow, and thus a value of the leakage current increases.

### SUMMARY

This Summary is provided to introduce a selection of concepts in a simplified form that are further described below in the Detailed Description. This Summary is not intended to identify all key features or essential features of the claimed subject matter, nor is it intended to be used alone as an aid in determining the scope of the claimed subject matter.

One purpose of the present disclosure is to provide a method for manufacturing a semiconductor light emitting device in which leakage current is removed or minimized using an atomic layer etching process.

Another purpose of the present disclosure is to provide a semiconductor light emitting device manufactured by the above semiconductor light emitting device manufacturing method.

Purposes in accordance with the present disclosure are not limited to the above-mentioned purpose. Other purposes and advantages in accordance with the present disclosure as not mentioned above may be understood from following descriptions and more clearly understood from embodiments in accordance with the present disclosure. Further, it will be readily appreciated that the purposes and advantages in accordance with the present disclosure may be realized by features and combinations thereof as disclosed in the claims.

One aspect of the present disclosure provides a method for manufacturing a semiconductor light emitting device, the method comprising: a first step of forming a semiconductor structure in which a first conductive-type semiconductor layer, an active layer, and a second conductive-type semiconductor layer are sequentially stacked; and a second step of forming a mesa structure by removing a portion of each of the second conductive-type semiconductor layer and the active layer, wherein the second step includes: forming a mesa structure by etching a portion of each of the second conductive-type semiconductor layer and the active layer using a plasma etching process; and performing an atomic layer etching process on a surface of the mesa structure formed by the plasma etching process.

In one implementation of the method, the atomic layer etching process includes a dry etching process using a remote etching source as one of an ion beam, a neutral beam, and an electron beam.

In one implementation of the method, the atomic layer etching process includes: a first process of forming an adsorption layer on a surface of the semiconductor structure using a first gas chemically adsorbed on the surface of the semiconductor structure; and a second process of etching a portion of the adsorption layer and the semiconductor structure using a second gas generating the etching source.

In one implementation of the method, the first gas includes at least one halogen element, wherein the second gas includes at least one selected from a group consisting of an halogen element and inert gas.

In one implementation of the method, the atomic layer etching process is performed using a remote etching apparatus, wherein the apparatus includes: a first chamber for generating the etching source; a second chamber for receiving the semiconductor structure; and an etching source extractor for extracting the etching source from the first chamber and irradiating the extracted etching source to the semiconductor structure in the second chamber.

In one implementation of the method, the etching source is irradiated at an angle in a range of 20° to 70° with respect to a surface of the second conductive-type semiconductor layer.

In one implementation of the method, the mesa structure is formed such that a ratio (L/A) of a side edge length (L) relative to an area (A) of a top face of the mesa structure is in a range of 0.05 to 0.080 μm⁻¹.

Another aspect of the present disclosure provides a semiconductor light emitting device comprising a semiconductor structure, wherein the semiconductor structure includes; a first conductive-type semiconductor layer; a second conductive-type semiconductor layer disposed on the first conductive-type semiconductor; and an active layer disposed between the first conductive-type semiconductor layer and the second conductive-type semiconductor layer, wherein the semiconductor structure has a mesa structure, wherein the semiconductor structure exhibits a first operation voltage characteristic and a second operation voltage characteristic, respectively when a non-emitting current of 1 uA and an emitting current of 20 uA are applied to the semiconductor structure, wherein a ratio (VF1uA/VF20uA) of the first operation voltage relative to the second operation voltage is in a range of 0.855 V/V to 1.000 V/V.

In one implementation of the device, a ratio (L/A) of a side edge length (L) relative to an area (A) of a top face of the mesa structure is in a range of 0.05 to 0.080 μm⁻¹.

In one implementation of the device, the top face of the mesa structure has a rectangular shape having a first side edge and a second side edge perpendicular thereto, wherein a ratio of a length of the first side edge and a length of the second side edge exceeds 1:1 and is smaller than or equal to 1:10.

In one implementation of the device, the device further comprises a gate electrode, a source electrode, and a drain electrode, wherein the current applied to the semiconductor structure is a current applied across the drain electrode and the source electrode.

According to the present disclosure, damage to the surface of the semiconductor light emitting device as caused by the conventional process may be reduced using an atomic layer etching process in addition to the conventional plasma etching process.

Accordingly, the leakage current resulting from the damage to the surface of the semiconductor light emitting device is eliminated or minimized Thus, the semiconductor light emitting device manufactured using the manufacturing method according to the present disclosure exhibits superior voltage characteristics to that of the conventional semiconductor light emitting device.

In addition, damage to the surface of the semiconductor light emitting device further accelerates defects in the semiconductor due to the leakage current, thereby causing degradation of the semiconductor light emitting device. However, the manufacturing method of the semiconductor light emitting device according to the present disclosure may improve reliability of the semiconductor light emitting device by removing or minimizing the leakage current of the semiconductor light emitting device.

In addition to the effects as described above, specific effects in accordance with the present disclosure will be described together with following detailed descriptions for carrying out the disclosure.

### BRIEF DESCRIPTION OF DRAWINGS

FIG. 1 schematically shows a structure of a semiconductor light emitting device according to the present disclosure.

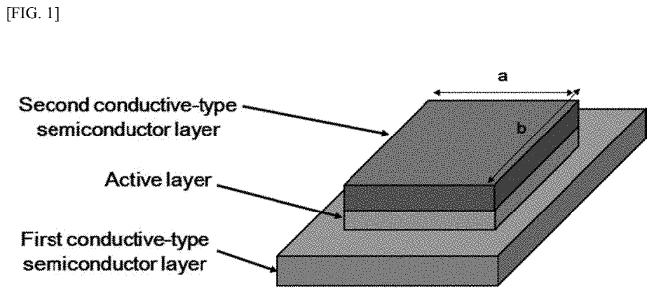

FIG. 2 shows a graph showing a first voltage characteristic at a non-emitting current VF0.1uA and a second voltage characteristic at a emitting current VF20uA based on the number of cycles of an atomic layer etching process.

FIG. 3 shows a graph of a ratio (VF1uA/VF20uA) of a first operation voltage relative to a second operation voltage, based on a perimeter/area as a ratio (L/A) of a side edge length (L) relative to an area (A) of a top face of a mesa structure.

FIG. 4 shows a graph showing an etching rate based on an etching source irradiation angle relative to a surface of a second conductive-type semiconductor layer.

### DETAILED DESCRIPTIONS

For simplicity and clarity of illustration, elements in the figures are not necessarily drawn to scale. The same reference numbers in different figures represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

The terminology used herein is for the purpose of describing particular embodiments only and is not intended to limit the present disclosure. As used herein, the singular forms “a” and “an” are intended to include the plural forms as well, unless the context clearly indicates otherwise. It will be further understood that the terms “comprises”, “comprising”, “includes”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entirety of list of elements and may not modify the individual elements of the list. When referring to “C to D”, this means C inclusive to D inclusive unless otherwise specified.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In addition, it will also be understood that when a first element or layer is referred to as being present “on” or “beneath” a second element or layer, the first element may be disposed directly on or beneath the second element or may be disposed indirectly on or beneath the second element with a third element or layer being disposed between the first and second elements or layers.

It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a manufacturing method of a semiconductor light emitting device using an atomic layer etching process according to the present disclosure will be described in more detail with reference to the drawings of the present disclosure.

<Method of Manufacturing Semiconductor Light Emitting Device>

A method for manufacturing a semiconductor light emitting device according to an embodiment of the present disclosure includes: a first step of forming a semiconductor structure in which a first conductive-type semiconductor layer, an active layer, and a second conductive-type semiconductor layer are sequentially stacked; and a second step of forming a mesa structure by removing a portion of each of the second conductive-type semiconductor layer and the active layer, wherein the second step includes: forming a mesa structure by etching a portion of each of the second conductive-type semiconductor layer and the active layer using a plasma etching process; and performing an atomic layer etching process on a surface of the mesa structure formed by the plasma etching process.

First, the semiconductor structure in which the first conductive-type semiconductor layer, the active layer, and the second conductive-type semiconductor layer are sequentially stacked will be described.

The first conductive-type semiconductor layer, the active layer, and the second conductive-type semiconductor layer may be sequentially stacked.

The first conductive-type semiconductor layer may be one of a P-type semiconductor layer and an N-type semiconductor layer, while the second conductive-type semiconductor layer may be the other of a P-type semiconductor layer and an N-type semiconductor layer.

The active layer may be made of, for example, a GaN-based compound which may be selected from a group consisting of GaN, AlN, InN, AlGaN, and InGaN.

Next, the mesa structure formed by removing a portion of each of the second conductive-type semiconductor layer and the active layer will be described.

The mesa refers to a table-shaped terrain having a flat top and a steep sloped side face. The mesa structure in the semiconductor field is one of classification types of the semiconductor devices according to a structure. An PN junction of the two conductive-type semiconductor layers forms a table shape as the mesa. This is widely used in high power devices. In order to form such a mesa structure, a process of removing a portion of each of the upper conductive-type semiconductor layer and the active layer except for the lower conductive-type semiconductor layer is required. However, a surface of the active layer in a mesa surface of a LED structure is exposed to an outside, and the exposed surface acts as cause of the leakage current in the semiconductor light emitting device due to surface recombination.

Next, the second step includes: forming a mesa structure by etching a portion of each of the second conductive-type semiconductor layer and the active layer using a plasma etching process; and performing an atomic layer etching process on a surface of the mesa structure formed by the plasma etching process. This second step will be described.

The plasma etching process is one of the most common methods used to form the mesa structure. This plasma etching process may belong to dry etching among two typical types of etching, that is, dry etching and wet etching. The plasma etching process may anisotropically etch the semiconductor structure using plasma radiated at a low pressure. The plasma etching process may include reactive ion etching (RIE), induced coupled plasma (ICP) etching, electron cyclotron resonance (ECR) etching, and high density plasma (HDP) etching, etc.

The atomic layer etching process is currently receiving the most attention, and may etch/remove an ultra-thin layer of a material, that is, an atomic layer. Thus, the etching process may be controlled at an atomic level, thereby enabling much more precise etching, compared to the conventional etching process. The atomic layer etching process is far superior in selectively removing only a target material without removing a basic material.

The atomic layer etching process may include, specifically, a first process of forming an adsorption layer on the surface of the semiconductor structure using a first gas chemically adsorbed on the surface of the semiconductor structure; a second process of etching a portion of the adsorption layer and the semiconductor structure using a second gas generating the etching source.

In this connection, the first gas may include one or more halogen elements, and specifically, at least one or more of F, Cl, and Br elements. For example, the first gas including one or more halogen elements may include HF, NF₃, Cl₂, HCl, SF₆, HBr, CF₄, BCl₃, C₃F₈, SiF₄, C₂F₈, and the like, and in particular, hydrogen fluoride (HF).

The second gas may include one or more selected from a group consisting of a halogen element and an inert gas, and specifically, may include at least one or more of Ar, Kr, and Ne elements. For example, the second gas selected from the group consisting of a halogen element and an inert gas may include argon (Ar).

In one implementation of the method, the atomic layer etching process is performed using a remote etching apparatus, wherein the apparatus includes: a first chamber for generating the etching source; a second chamber for receiving the semiconductor structure; and an etching source extractor for extracting the etching source from the first chamber and irradiating the extracted etching source to the semiconductor structure in the second chamber.

In this connection, the remote etching is referred to as remote plasma etching. The remote etching apparatus may include a first chamber that generates plasma to generate an etching source, a second chamber where semiconductor etching substantially occurs, and an etching source extractor that functions to extract only the etching source from the first chamber and irradiate the extracted etching source to the semiconductor structure of the second chamber. In the remote etching apparatus, the plasma generation chamber and the etching process chamber are separated from each other, thereby to prevent electrons, ions, or ultraviolet rays from reaching the semiconductor structure and thus to reduce the damage caused by the electrons, ions, or ultraviolet rays.

The atomic layer etching process is characterized by using one of an ion beam, a neutral beam, and an electron beam as the remote etching source.

Plasma is a gas that is partially ionized via a discharge process of a magnetic field, and contains all of neutral molecules and ions and electrons separated therefrom. The etching source used in the atomic layer etching process may include all three types of plasma, such as ion beam, neutral beam, and electron beam. The etching process may be performed using selected one among the three types of plasma.

In one implementation of the method, the etching source is irradiated at an angle in a range of 20° to 70° with respect to a surface of the second conductive-type semiconductor layer.

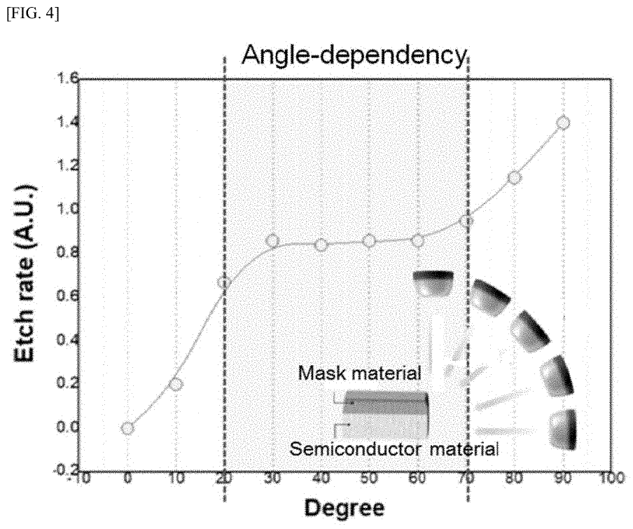

The irradiation angle of the etching source is an important factor influencing the etching rate. It is disclosed that the etching rate varies based on the irradiation angle of the etching source, as shown in the attached FIG. 4. It may be identified that when the irradiation angle of the etching source is lower than 20°, the etching rate is not constant and rapidly decreases. To the contrary, it may be identified that when the irradiation angle of the etching source exceeds 70°, the etching rate is not constant and rises rapidly. Thus, the etching process may produce a resulting structure having excessive or insufficient, and non-uniform etching rate, and may adversely affect the formation of the mesa structure of the semiconductor structure. As shown in the attached FIG. 4, when the etching source is irradiated at an angle in a range of 20° to 70° with respect to the surface of the second conductive-type semiconductor layer, the resulting structure from the etching process has a constant value in a range of 0.6 to 0.9 of the etching rate.

A semiconductor light emitting device according to an embodiment of the present disclosure has a semiconductor structure, wherein the semiconductor structure includes; a first conductive-type semiconductor layer; a second conductive-type semiconductor layer disposed on the first conductive-type semiconductor; and an active layer disposed between the first conductive-type semiconductor layer and the second conductive-type semiconductor layer, wherein the semiconductor structure has a mesa structure, wherein the semiconductor structure exhibits a first operation voltage characteristic and a second operation voltage characteristic, respectively when a non-emitting current of 1 uA and an emitting current of 20 uA are applied to the semiconductor structure, wherein a ratio (VF1uA/VF20uA) of the first operation voltage relative to the second operation voltage is in a range of 0.855 V/V to 1.000 V/V.

In one implementation of the device, a ratio (L/A) of a side edge length (L) relative to an area (A) of a top face of the mesa structure is in a range of 0.05 to 0.080 μm⁻¹.

First, the characteristics of the first operation voltage and the second operation voltage of the semiconductor structure will be described.

When a non-emitting current of 1 uA is applied to the semiconductor structure, the semiconductor structure has the first operation voltage. In this connection, the first operation voltage is the largest voltage among voltages below a voltage corresponding to the non-emitting current at which the semiconductor structure does not emit light. On the other hand, when a 20 uA emitting current is applied to the semiconductor structure, the semiconductor structure has the second operation voltage. In this connection, the second operation voltage corresponds to the emitting current at which the semiconductor structure emits light.

The operation voltage acts as one of the indicators for evaluating the performance of the semiconductor light emitting device. The operation voltage may indicate the effect of the etching process disclosed in the present disclosure.

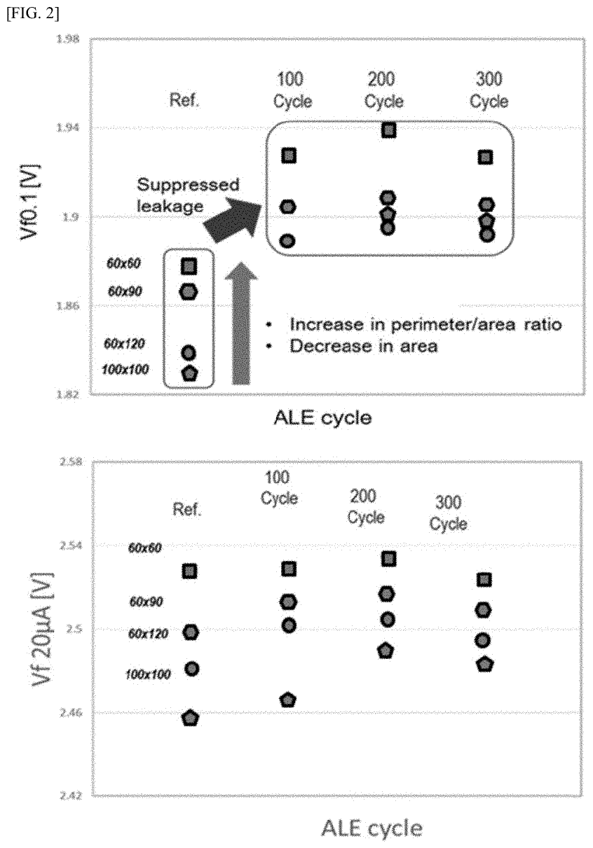

FIG. 2 shows the values of the first operation voltage and the second operation voltage based on the number of cycles of the atomic layer etching process for etching the semiconductor structure. In an example used to derive the graph of FIG. 2, the non-emitting current used in FIG. 2 is 0.1 uA, the emitting current used in FIG. 2 is 20 uA, and an area of the top face of the mesa structure of the semiconductor structure is 60*60 μm², 60*90 μm², 60*120 μm² and 100*100 μm².

As shown in FIG. 2, when the atomic layer etching process is applied, and when the non-emitting current is applied to the semiconductor structure, the voltage characteristic is significantly improved (as indicated by a red arrow in a VF0.1uA graph), compared to a sample to which the atomic layer etching process is not applied. This means that the atomic layer etching process exhibits superior first voltage characteristics, compared to the conventional etching process, that is, means that the voltage increase rate at the non-emitting current is large. This leads to improved reliability and light output efficiency of the semiconductor light emitting device.

[Table 1] below shows the first operation voltage (VF1uA), and the second operation voltage based on the area of the top face of the mesa structure of the semiconductor structure. As may be identified in the table below, when applying the atomic layer etching process, higher voltage characteristics are exhibited for all sizes of the top face, compared to a sample (Ref.) that has been etched only using the conventional process.

TABLE 1

| | | | | Vf [at 20 uA] | | | |
|---|---|---|---|---|---|---|---|
| | Perimeter | Area | Perimeter/ | Operation voltage | | Vf [at 1 uA] | |
| Pattern | [um] | [um²] | area | ALE200 | Ref. | ALE200 | REF |
| 60 × 120 | 360 | 7,200 | 5.00E−02 | 2.502 | 2.496 | 2.152 | 2.096 |
| 60 × 90 | 300 | 5,400 | 5.56E−02 | 2.514 | 2.508 | 2.176 | 2.125 |
| 60 × 60 | 240 | 3,600 | 6.67E−02 | 2.53 | 2.525 | 2.194 | 2.15 |
| 80 × 80 | 320 | 6,400 | 5.00E−02 | 2.504 | 2.498 | 2.169 | 2.116 |
| 100 * 100 | 400 | 10,000 | 4.00E−02 | 2.467 | 2.483 | 2.14 | 2.073 |

Next, the ratio (L/A) of the side edge length (L) relative to the area (A) of the top face of the mesa structure will be described.

The mesa structure is characterized in that the ratio (L/A) of the side edge length (L) relative to the area (A) of the top face thereof is in a range of 0.05 to 0.080 μm⁻¹.

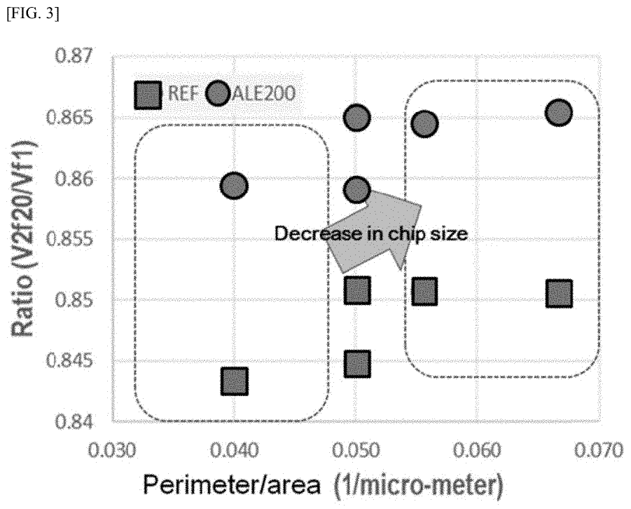

FIG. 3 shows a graph of a ratio (VF1uA/VF20uA) of a first operation voltage relative to a second operation voltage, based on a perimeter/area as a ratio (L/A) of a side edge length (L) relative to an area (A) of a top face of a mesa structure. The ratio (L/A) of the side edge length (L) relative to the area (A) of the top face of the mesa structure acts as an indicator indicating a size of the chip. As the ratio increases, the size of the chip decreases.

As shown in FIG. 3, as the perimeter/area of the top face of the mesa structure increases, that is, as the size of the chip decreases, the ratio (VF1uA/VF20uA) of the first operation voltage relative to the second operation voltage increases regardless of whether the atomic layer etching process is applied. Thus, the atomic layer etching process according to the present disclosure may be applied to small-sized chips in a more useful manner.

[Table 2] below summarizes the graph of [FIG. 3] as a table. It may be identified from the table below that the smaller a size of a pattern composed of the mesa structure, the lower the ratio (VF1uA/VF20uA) of the first operation voltage relative to the second operation voltage. In addition, when the pattern size has 80*80, but a length of one side of the pattern increases to 120, the ratio (VF1uA/VF20uA of the first operation voltage relative to the second operation voltage) decreases.

TABLE 2

| | Perimeter/Area | Ratio (VF1uA/VF20uA) | |
|---|---|---|---|
| Pattern size | [2(a + b)/(ab)] | REF | ALE200 |
| 100 × 100 | 0.040 | 0.8434 | 0.8594 |
| 80 × 80 | 0.050 | 0.8508 | 0.8652 |
| 60 × 120 | 0.050 | 0.8448 | 0.8591 |
| 60 × 90 | 0.056 | 0.8507 | 0.8645 |
| 60 × 60 | 0.067 | 0.8505 | 0.8655 |

Next, the ratio (VF1uA/VF20uA) of the first operation voltage relative to the second operation voltage will be described.

The ratio (VF1uA/VF20uA) of the first operation voltage relative to the second operation voltage may be in a range of 0.855 V/V to 1.000 V/V.

As may be further identified in the [Table 2], the ratio (VF1uA/VF20uA) of the first operation voltage relative to the second operation voltage is lower than 0.851V/V in all examples in which the atomic layer etching process is not applied. In all of the examples in which 200 cycles of the atomic layer etching process are applied, the ratio (VF1uA/VF20uA) of the first operation voltage relative to the second operation voltage exceeds 0.859 V/V.

Accordingly, the ratio (VF1uA/VF20uA) of the first operation voltage relative to the second operation voltage is further improved voltage when applying the atomic layer etching process to the semiconductor structure, compared to the semiconductor light emitting device that the atomic layer etching process is not applied.

Although the embodiments of the present disclosure have been described in more detail with reference to the accompanying drawings, the present disclosure is not necessarily limited to these embodiments. The present disclosure may be implemented in various modified manners within the scope not departing from the technical idea of the present disclosure. Accordingly, the embodiments disclosed in the present disclosure are not intended to limit the technical idea of the present disclosure, but to describe the present disclosure. the scope of the technical idea of the present disclosure is not limited by the embodiments. Therefore, it should be understood that the embodiments as described above are illustrative and non-limiting in all respects. The scope of protection of the present disclosure should be interpreted by the claims, and all technical ideas within the scope of the present disclosure should be interpreted as being included in the scope of the present disclosure.

What is claimed is:

1. A method for manufacturing a semiconductor light emitting device, the method comprising:
a first step of forming a semiconductor structure in which a first conductive-type semiconductor layer, an active layer, and a second conductive-type semiconductor layer are sequentially stacked; and
a second step of forming a mesa structure by removing a portion of each of the second conductive-type semiconductor layer and the active layer,
wherein the second step includes:
forming a mesa structure by etching a portion of each of the second conductive-type semiconductor layer and the active layer using a plasma etching process; and
performing an atomic layer etching process on a surface of the mesa structure formed by the plasma etching process.

2. The method of claim 1, wherein the atomic layer etching process includes a dry etching process using a remote etching source as one of an ion beam, a neutral beam, and an electron beam.

3. The method of claim 2, wherein the atomic layer etching process includes:
a first process of forming an adsorption layer on a surface of the semiconductor structure using a first gas chemically adsorbed on the surface of the semiconductor structure; and
a second process of etching a portion of the adsorption layer and the semiconductor structure using a second gas generating the etching source.

4. The method of claim 3, wherein the first gas includes at least one halogen element, wherein the second gas includes at least one selected from a group consisting of an halogen element and inert gas.

5. The method of claim 3, wherein the atomic layer etching process is performed using a remote etching apparatus, wherein the apparatus includes:
a first chamber for generating the etching source;
a second chamber for receiving the semiconductor structure; and
an etching source extractor for extracting the etching source from the first chamber and irradiating the extracted etching source to the semiconductor structure in the second chamber.

6. The method of claim 5, wherein the etching source is irradiated at an angle in a range of 20° to 70° with respect to a surface of the second conductive-type semiconductor layer.

7. The method of claim 5, wherein the mesa structure is formed such that a ratio (L/A) of a side edge length (L) relative to an area (A) of a top face of the mesa structure is in a range of 0.05 to 0.080 μm⁻¹.

8. A semiconductor light emitting device comprising a semiconductor structure, wherein the semiconductor structure includes;
a first conductive-type semiconductor layer;
a second conductive-type semiconductor layer disposed on the first conductive-type semiconductor; and
an active layer disposed between the first conductive-type semiconductor layer and the second conductive-type semiconductor layer,
wherein the semiconductor structure has a mesa structure,
wherein the semiconductor structure exhibits a first operation voltage characteristic and a second operation voltage characteristic, respectively when a non-emitting current of 1 uA and an emitting current of 20 uA are applied to the semiconductor structure,
wherein a ratio (VF1uA/VF20uA) of the first operation voltage relative to the second operation voltage is in a range of 0.855 V/V to 1.000 V/V.

9. The device of claim 8, wherein a ratio (L/A) of a side edge length (L) relative to an area (A) of a top face of the mesa structure is in a range of 0.05 to 0.080 μm⁻¹.

10. The device of claim 8, wherein the top face of the mesa structure has a rectangular shape having a first side edge and a second side edge perpendicular thereto,
wherein a ratio of a length of the first side edge and a length of the second side edge exceeds 1:1 and is smaller than or equal to 1:10.

11. The device of claim 8, wherein the device further comprises a gate electrode, a source electrode, and a drain electrode,
wherein the current applied to the semiconductor structure is a current applied across the drain electrode and the source electrode.
